(19) United States
(12) Patent Application Publication
(10) Pub. No.: US 2022/0059598 A1
(43) Pub. Date: Feb. 24, 2022

(54) Method for Detecting Depth of Vertical Gate of Transfer Transistor of CMOS Image Sensor

(71) Applicant: Shanghai Huali Microelectronics Corporation, Shanghai (CN)

(72) Inventors: Zhi Tian, Shanghai (CN); Juanjuan Li, Shanghai (CN); Hua Shao, Shanghai (CN); Haoyu Chen, Shanghai (CN)

(73) Assignee: Shanghai Huali Microelectronics Corporation, Shanghai (CN)

(21) Appl. No.: 16/951,038

(22) Filed: Nov. 18, 2020

(30) Foreign Application Priority Data
Aug. 18, 2020 (CN) 202010831333.4

(51) Int. Cl. H01L 27/146; H01L 27/148

(52) U.S. Cl. CPC H01L 27/14643; H01L 27/14612; H01L 27/14831

(57) ABSTRACT

The disclosure discloses a method for detecting the depth of a vertical gate of a transfer transistor of a CMOS image sensor. The effective electrical thickness of planar gate polysilicon of a transfer transistor of a reference CMOS image sensor is obtained through a planar test, the capacitance of a vertical gate structure of a transfer transistor of a to-be-tested CMOS image sensor is obtained through a vertical test, and then the equivalent depth of the vertical gate of the transfer transistor of the to-be-tested CMOS image sensor is calculated accordingly. The depth of the gates of the transfer transistors of all CMOS image sensors can be monitored on line without damaging a silicon wafer, it is conducive to finding the abnormality of the depth of the gates of the transfer transistors in time, and the product quality of the CMOS image sensor can be effectively monitored.

### CROSS-REFERENCES TO RELATED APPLICATIONS

This application claims priority to Chinese Patent Application No. 202010831333.4, filed on Aug. 18, 2020, and entitled “Method for Detecting Depth of Vertical Gate of Transfer Transistor of CMOS Image Sensor”, the disclosure of which is incorporated herein by reference in entirety.

### TECHNICAL FIELD

The disclosure relates to a semiconductor detection technology and in particular to a method for detecting the depth of a vertical gate of a transfer transistor of a CMOS image sensor.

### BACKGROUND

CMOS image sensors have been developed rapidly in the past decade, and have been widely applied to mobile phones, computers, digital cameras and other fields. In order to meet the market demand and integrate more pixel units per unit area, the pixel size of the CMOS image sensor has been gradually reduced from 5.6 mm to 1.0 mm. However, the reduction of the pixel size cannot be simply equivalent to the reducing the size of a photodiode in all directions, because of the limitation of the effective Full Well Capacity (FWC) of the photodiode. If the size is too small, consequently enough electrons cannot be stored and the image quality will be degraded seriously.

The basic structure of a common 4T CMOS image sensor is as illustrated in FIG. 1, which consists of a photodiode (PD) 10, a transfer transistor (Tx) 11, a reset transistor (RST) 13, an amplify transistor (SF) 14 and a row select transistor (RS) 15. When the transfer transistor (Tx) 11 is turned off for photosensitization, a P-N junction of the photodiode (PD) 10 captures sunlight to generate electrons and holes. Under the effect of the built-in electric field of the P-N junction, the photo-generated electrons accumulate towards the top. When the gate of the transfer transistor (Tx) 11 is powered and turned on, the electrons are transmitted to a floating diffusion region 12 between the transfer transistor (Tx) 11 and the reset transistor (RST) 13 through a surface channel, and then are read. The transfer path of the electrons is as illustrated in FIG. 2. In this way of electron transmission, the pathway is small, the electrons deep in the photodiode need to pass through the whole junction region for the purpose of transmission, and recombination is caused very easily, resulting in low extraction efficiency. In addition, time and voltage drive are needed to complete the transmission of the electrons deep in P-N junction, which is not conducive to fast reading. In order to increase the speed and efficiency of electron transfer, it is an effective way to develop a three-dimensional pixel region to replace the traditional two-dimensional channel structure to solve the above problem.

Referring to FIG. 3, the development of vertical gates can extend a channel deep into a photodiode, such that an electron transmission channel is changed from a planar channel to a three-dimensional channel, transmission channels of electrons are multiplied, the transmission speed of photo-generated electrons is greatly increased, and the deepening of the channel can reduce the residual electrons in the photodiode, improve the utilization ratio of the photo-generated electrons and finally improve the full well capacity of the photodiode. However, since the size of a vertical gate structure for small pixels is small and an obvious load effect exists during silicon etching (the depth corresponding to large size and small size is greatly different), the depth of the vertical gate in a large area is smaller than the normal small size, referring to FIG. 3 and FIG. 4, such that the depth of the vertical gate of the transfer transistor (Tx) cannot be detected in a normal way, and have to adopted destructive slicing to detect the depth of the vertical gate.

### BRIEF SUMMARY

The technical problem to be solved by the disclosure is to provide a method for detecting the depth of a vertical gate of a transfer transistor of a CMOS image sensor, which can effectively monitor the depth of the vertical gate and monitor the depth of the gates of the transfer transistors of all CMOS image sensors on line without damaging a silicon wafer.

In order to solve the above technical problem, in the method for detecting the depth of the vertical gate of the transfer transistor of the CMOS image sensor provided by the disclosure, vertical gate polysilicon of a transfer transistor of a to-be-tested CMOS image sensor includes a flat portion and n vertical columns, wherein n is a positive integer; the flat portion is formed on the surface of a first type doped epitaxial layer; the upper ends of the n vertical columns are connected with the flat portion and are formed in the first type doped epitaxial layer. The method includes the following steps:

1) detecting the effective electrical thickness EOT of planar gate polysilicon of a transfer transistor of a reference CMOS image sensor, the gate polysilicon of the transfer transistor of the reference CMOS image sensor being formed on the surface of the first type doped epitaxial layer and having the same cross-sectional shape as the flat portion of the vertical gate polysilicon of the transfer transistor of the to-be-tested CMOS image sensor;

detecting the capacitance C_{ox(VTG)} of a vertical gate structure of the transfer transistor of the to-be-tested CMOS image sensor;

2) calculating the depth H of the vertical gate of the transfer transistor of the to-be-tested

CMOS image sensor,

$$H = \frac{[ \frac{{C}_{ox ( V T G )} * EOT}{{ɛ}_{0} {ɛ}_{r}} - W ) ]}{w * n} ;$$

where ε₀ is a vacuum dielectric constant; εᵣ is a relative dielectric constant; W is the cross-sectional area of the flat portion; w is the cross-sectional area of one vertical column of the vertical gate polysilicon.

Preferably, the cross section of the flat portion is rectangular.

Preferably, the cross section of the flat portion is square.

Preferably, w=2π*r , each vertical column of the vertical gate polysilicon is cylindrical, and r is the cross-sectional radius of each cylindrical vertical column of the vertical gate polysilicon.

Preferably, n is 7, 8, 9 or 10.

Preferably, the n vertical columns are uniformly formed in the first type doped epitaxial layer.

Preferably, the CMOS image sensor includes a photodiode, a transfer transistor, a floating diffusion region and a reset transistor which are adjacent sequentially;

the photodiode includes a second conducting type photosensitive doped region formed at the top of the first type doped epitaxial layer;

a first conducting type doped pinned layer is formed on the surface of the second conducting type photosensitive doped region;

the floating diffusion region is formed in a first type doped well;

a gate structure of the transfer transistor is formed at the top of the first type doped epitaxial layer between the floating diffusion region and the photodiode.

Preferably, the CMOS image sensor further includes a resetting region;

a gate structure of the reset transistor is formed between the floating diffusion region and the resetting region;

the floating diffusion region and the resetting region are formed in the first type doped well;

the resetting region is subjected to second conducting type doping;

the resetting region is configured to connect with power supply voltage;

a gate of an amplify transistor is connected with the floating diffusion region, a source outputs an amplified signal, and a drain is connected with the power supply voltage;

a select transistor is configured to select and output the amplified signal output by the amplify transistor;

a gate of the select transistor is connected with a select signal.

Preferably, the first conducting type is N-type, and the second conducting type is P-type; or

the first conducting type is P-type, and the second conducting type is N-type.

In the method for detecting the depth of the vertical gate of the transfer transistor of the CMOS image sensor provided by the disclosure, through the combination of planar and vertical gates with the same layout area, the effective electrical thickness EOT of planar gate polysilicon of the transfer transistor of the reference CMOS image sensor is obtained through a planar test, the capacitance C_{ox(VTG)} of the vertical gate structure of the transfer transistor of the to-be-tested CMOS image sensor is obtained through a vertical test, and then the equivalent depth of the vertical gate of the transfer transistor of the to-be-tested CMOS image sensor is calculated accordingly. The depth of the vertical gate can be effectively monitored, the depth of the gates of the transfer transistors of all CMOS image sensors can be monitored on line without damaging a silicon wafer, it is conducive to finding the abnormality of the depth of the gates of the transfer transistors in time, and the product quality of the CMOS image sensor can be effectively monitored.

### BRIEF DESCRIPTION OF THE DRAWINGS

In order to more clearly describe the technical solution of the disclosure, the drawings which need be used in the disclosure will be briefly introduced below. Apparently, the drawings described below are just some embodiments of the disclosure. Those skilled in the art may obtain other drawings according to these drawings without contributing any inventive labor.

FIG. 1 is a basic structure of a 4T CMOS image sensor.

FIG. 2 is a schematic view of electron transfer after a transfer transistor is turned on in a

CMOS image sensor with a planar gate transfer transistor.

FIG. 3 is a schematic view of electron transfer after a transfer transistor is turned on in a

CMOS image sensor with a small-size vertical gate transfer transistor.

FIG. 4 is a schematic view of a CMOS image sensor with a large-size vertical gate transfer transistor.

FIG. 5 is a cross-sectional schematic view of a planar gate transfer transistor.

FIG. 6 is a three-dimensional schematic view of a planar gate transfer transistor.

FIG. 7 is a cross-sectional schematic view of a vertical gate transfer transistor.

FIG. 8 is a three-dimensional schematic view of a vertical gate transfer transistor.

### DETAILED DESCRIPTION OF THE DISCLOSURE

The technical solution of the disclosure will be described below clearly and completely with reference to the drawings. Apparently, the described embodiments are partial embodiments of the disclosure, instead of all embodiments. Based on the embodiments of the disclosure, all other embodiments obtained by those skilled in the art without contributing any inventive labor shall fall into the scope of protection of the disclosure.

### EMBODIMENT 1

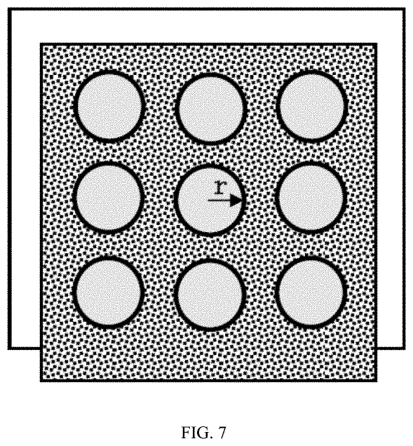

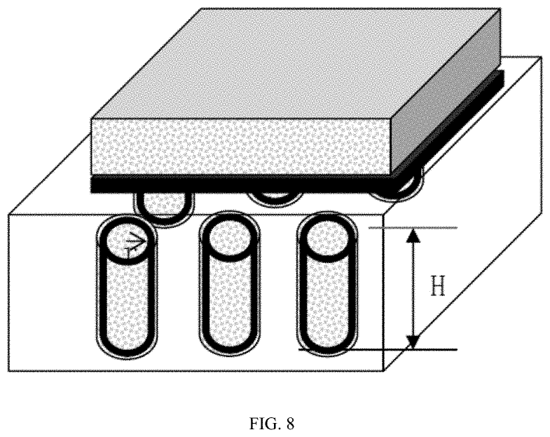

The present embodiment provides a method for detecting the depth of a vertical gate of a transfer transistor of a CMOS image sensor. Referring to FIG. 7 and FIG. 8, vertical gate polysilicon of a transfer transistor of a to-be-tested CMOS image sensor includes a flat portion and n vertical columns, wherein n is a positive integer; the flat portion is formed on the surface of a first type doped epitaxial layer; the upper ends of then vertical columns are connected with the flat portion and are formed in the first type doped epitaxial layer. The method includes the following steps:

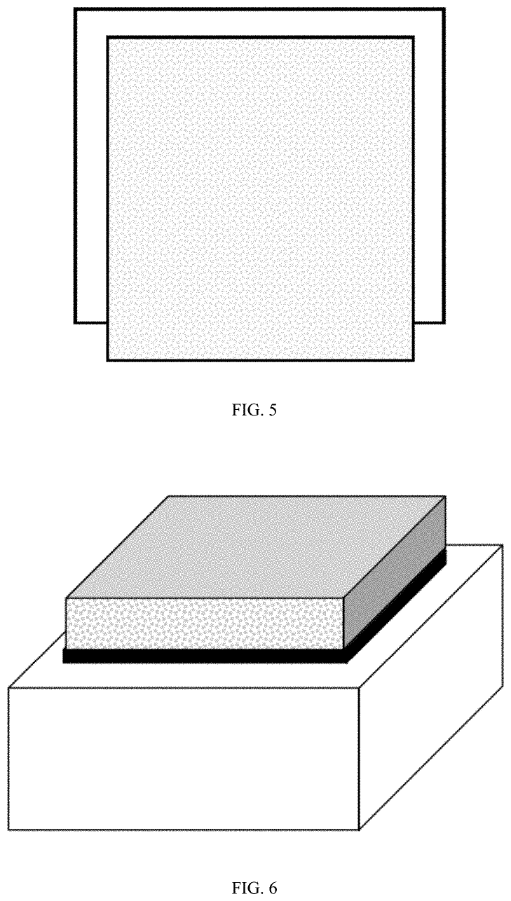

1) The effective electrical thickness EOT of planar gate polysilicon of a transfer transistor of a reference CMOS image sensor is detected. Referring to FIG. 5 and FIG. 6, the gate polysilicon of the transfer transistor of the reference CMOS image sensor is formed on the surface of the first type doped epitaxial layer and has the same cross-sectional shape as the flat portion of the vertical gate polysilicon of the transfer transistor of the to-be-tested CMOS image sensor.

The capacitance C_{ox(VTG)} of a vertical gate structure of the transfer transistor of the to-be-tested CMOS image sensor is detected;

2) The depth H of the vertical gate of the transfer transistor of the to-be-tested CMOS image sensor is calculated.

$$H = \frac{[ \frac{{C}_{ox ( V T G )} * EOT}{{ɛ}_{0} {ɛ}_{r}} - W ) ]}{w * n} \qquad ( formula 1 )$$

where ε₀ is a vacuum dielectric constant; εᵣ is a relative dielectric constant; W is the cross-sectional area of the flat portion; w is the cross-sectional area of one vertical column of the vertical gate polysilicon.

The effective electrical thickness EOT of the planar gate polysilicon of the transfer transistor of the reference CMOS image sensor can be conveniently obtained through a test.

The capacitance C_{ox(VTG)} of the vertical gate structure of the transfer transistor of the to-be-tested CMOS image sensor can be conveniently obtained through a test.

$$\begin{matrix}{S}_{t o t a l} = W + w * H * n , & ( formula 2 ) ; \\ EOT = \frac{{ɛ}_{0} {ɛ}_{r} W}{{C}_{o x ( b u l k )}} , & ( formula 3 ) ; \\ {C}_{o x ( V T G )} = \frac{{ɛ}_{0} {ɛ}_{r} {S}_{t o t a l}}{E O T} , & ( formula 4 )\end{matrix}$$

where Sₜₒₜₐₗ is a sum of surface area of the flat portion and all vertical columns, which are in contact with the epitaxial layer, of the gate polysilicon of the transfer transistor of the to-be-tested CMOS image sensor;

C_{ox(bulk)} is the capacitance of silicon oxide of the gate polysilicon with a rectangular cross section.

According to formula (2), formula (3) and formula (4), taking w=2π*r, formula 1 can be obtained.

In the method for detecting the depth of the vertical gate of the transfer transistor of the CMOS image sensor provided embodiment 1, through the combination of planar and vertical gates with the same layout area, the effective electrical thickness EOT of planar gate polysilicon of the transfer transistor of the reference CMOS image sensor is obtained through a planar test, the capacitance C_{ox(VTG)} of the vertical gate structure of the transfer transistor of the to-be-tested CMOS image sensor is obtained through a vertical test, and then the equivalent depth of the vertical gate of the transfer transistor of the to-be-tested CMOS image sensor is calculated accordingly. The depth of the vertical gate can be effectively monitored, the depth of the gates of the transfer transistors of all CMOS image sensors can be monitored on line without damaging a silicon wafer, it is conducive to finding the abnormality of the depth of the gates of the transfer transistors in time, and the product quality of the CMOS image sensor can be effectively monitored.

### EMBODIMENT 2

Based on the method for detecting the depth of the vertical gate of the transfer transistor of the CMOS image sensor provided embodiment 1, the cross section of the flat portion is rectangular.

Preferably, the cross section of the flat portion is square.

Preferably, w=2π*r , each vertical column of the vertical gate polysilicon is cylindrical, and r is the cross-sectional radius of each cylindrical vertical column of the vertical gate polysilicon.

Preferably, n is 7, 8, 9 or 10.

Preferably, the n vertical columns are uniformly formed in the first type doped epitaxial layer.

### EMBODIMENT 3

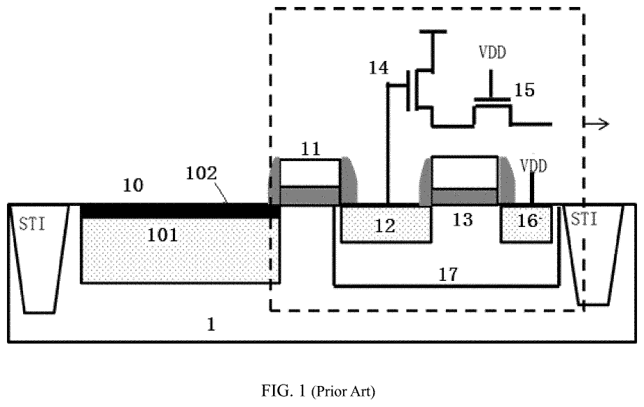

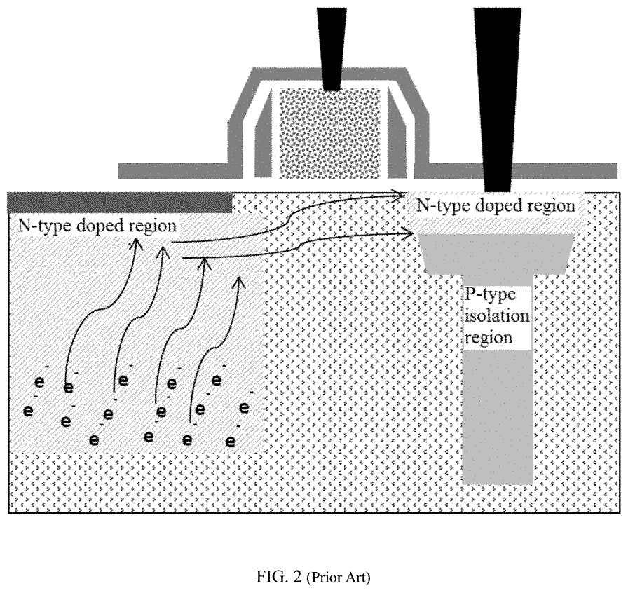

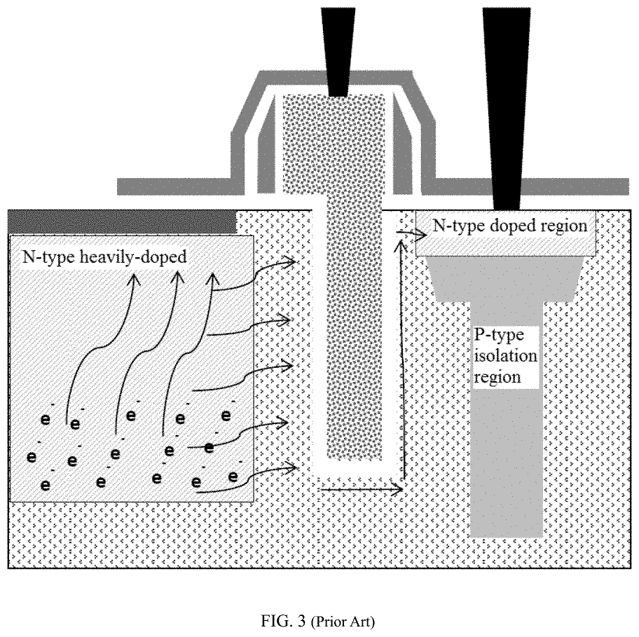

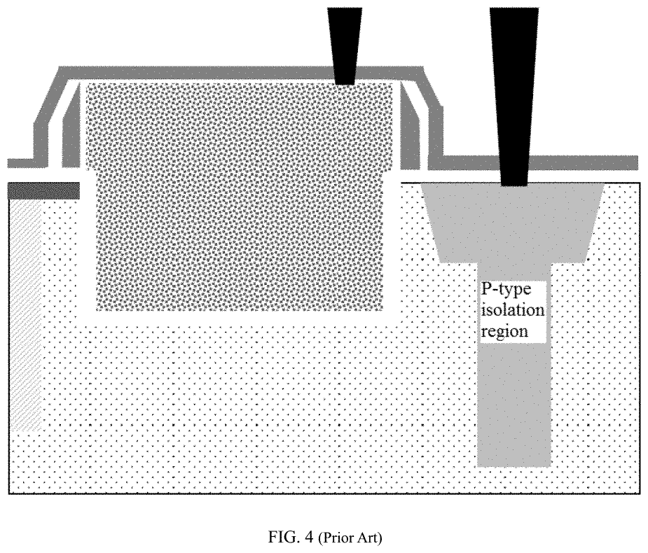

Based on the method for detecting the depth of the vertical gate of the transfer transistor of the CMOS image sensor provided embodiment 1, referring to FIG. 1, the CMOS image sensor includes a photodiode (PD) 10, a transfer transistor (Tx) 11, a floating diffusion region (FD) 12 and a reset transistor (RST) 13 which are adjacent sequentially;

the photodiode 10 includes a second conducting type photosensitive doped region 101 formed at the top of the first type doped epitaxial layer 1;

a first conducting type doped pinned layer 102 is formed on the surface of the second conducting type photosensitive doped region 101;

the floating diffusion region 12 is formed in a first type doped well 17;

a gate structure of the transfer transistor 11 is formed at the top of the first type doped epitaxial layer 1 between the floating diffusion region 12 and the photodiode 10.

Preferably, the CMOS image sensor further includes a resetting region 16;

a gate structure of the reset transistor 13 is formed between the floating diffusion region 12 and the resetting region 16;

the floating diffusion region 12 and the resetting region 16 are formed in the first type doped well 17;

the resetting region 16 is subjected to second conducting type doping;

the resetting region 16 is configured to connect with power supply voltage VDD;

a gate of an amplify transistor 14 is connected with the floating diffusion region 12, a source outputs an amplified signal, and a drain is connected with the power supply voltage VDD;

a select transistor 15 is configured to select and output the amplified signal output by the amplify transistor 14;

a gate of the select transistor 15 is connected with a select signal Rs.

Preferably, the first conducting type is N-type, and the second conducting type is P-type;

or the first conducting type is P-type, and the second conducting type is N-type.

In the method for detecting the depth of the vertical gate of the transfer transistor of the CMOS image sensor provided by embodiment 3, when the transfer transistor (Tx) 11 is turned off for photosensitization, a P-N junction of the photodiode (PD) 10 captures sunlight to generate electrons and holes. Under the action of the built-in electric field of the P-N junction, the photo-generated electrons accumulate towards the top. When the gate of the transfer transistor (Tx) 11 is powered and turned on, the electrons are transmitted to the floating diffusion region 12 between the transfer transistor (Tx) 11 and the reset transistor (RST) 13 through a surface channel.

What are described above are just exemplary embodiments of the disclosure, which are not used to limit the disclosure. Any modification, equivalent replacement, improvement and the like made within the spirit and rule of the disclosure shall be included in the scope of protection of the disclosure.

What is claimed is:

1. A method for detecting the depth of a vertical gate of a transfer transistor of a CMOS image sensor, vertical gate polysilicon of a transfer transistor of a to-be-tested CMOS image sensor comprising a flat portion and n vertical columns, n being a positive integer; the flat portion being formed on the surface of a first type doped epitaxial layer; the upper ends of the n vertical columns being connected with the flat portion and being formed in the first type doped epitaxial layer, wherein the method comprises the following steps:
1) detecting the effective electrical thickness EOT of planar gate polysilicon of a transfer transistor of a reference CMOS image sensor, the gate polysilicon of the transfer transistor of the reference CMOS image sensor being formed on the surface of the first type doped epitaxial layer and having the same cross-sectional shape as the flat portion of the vertical gate polysilicon of the transfer transistor of the to-be-tested CMOS image sensor;
detecting the capacitance C_{ox(VTG)} of a vertical gate structure of the transfer transistor of the to-be-tested CMOS image sensor;
2) calculating the depth H of the vertical gate of the transfer transistor of the to-be-tested CMOS image sensor,
$$H = \frac{[ \frac{{C}_{ox ( V T G )} * EOT}{{ɛ}_{0} {ɛ}_{r}} - W ) ]}{w * n} ;$$
where ε₀ is a vacuum dielectric constant; εᵣ is a relative dielectric constant; W is the cross-sectional area of the flat portion; w is the cross-sectional area of one vertical column of the vertical gate polysilicon.

2. The method for detecting depth of the vertical gate of the transfer transistor of the CMOS image sensor according to claim 1, wherein
the cross section of the flat portion is rectangular.

3. The method for detecting depth of the vertical gate of the transfer transistor of the CMOS image sensor according to claim 1, wherein
the cross section of the flat portion is square.

4. The method for detecting depth of the vertical gate of the transfer transistor of the CMOS image sensor according to claim 1, wherein
w=2π*r, each vertical column of the vertical gate polysilicon is cylindrical, and r is the cross-sectional radius of each cylindrical vertical column of the vertical gate polysilicon.

5. The method for detecting depth of the vertical gate of the transfer transistor of the CMOS image sensor according to claim 1, wherein
n is 7, 8, 9 or 10.

6. The method for detecting depth of the vertical gate of the transfer transistor of the CMOS image sensor according to claim 1, wherein
the n vertical columns are uniformly formed in the first type doped epitaxial layer.

7. The method for detecting depth of the vertical gate of the transfer transistor of the CMOS image sensor according to claim 1, wherein
the CMOS image sensor comprises a photodiode, a transfer transistor, a floating diffusion region and a reset transistor which are adjacent sequentially;
the photodiode comprises a second conducting type photosensitive doped region formed at the top of the first type doped epitaxial layer;
a first conducting type doped pinned layer is formed on the surface of the second conducting type photosensitive doped region;
the floating diffusion region is formed in a first type doped well;
a gate structure of the transfer transistor is formed at the top of the first type doped epitaxial layer between the floating diffusion region and the photodiode.

8. The method for detecting depth of the vertical gate of the transfer transistor of the CMOS image sensor according to claim 7, wherein
the CMOS image sensor further comprises a resetting region;
a gate structure of the reset transistor is formed between the floating diffusion region and the resetting region;
the floating diffusion region and the resetting region are formed in the first type doped well;
the resetting region is subjected to second conducting type doping;
the resetting region is configured to connect with power supply voltage;
a gate of an amplify transistor is connected with the floating diffusion region, a source outputs an amplified signal, and a drain is connected with the power supply voltage;
a select transistor is configured to select and output the amplified signal output by the amplify transistor;
a gate of the select transistor is connected with a select signal.

9. The method for detecting depth of the vertical gate of the transfer transistor of the CMOS image sensor according to claim 8, wherein
the first conducting type is N-type, and the second conducting type is P-type; or
the first conducting type is P-type, and the second conducting type is N-type.
